(19) United States
(12) Patent Application Publication
(10) Pub. No.: US 2025/0226338 A1
(43) Pub. Date: Jul. 10, 2025

(54) Power Semiconductor Devices Including Shape-Memory Metallization

(71) Applicant: Wolfspeed, Inc., Durham, NC (US)

(72) Inventor: Afshin Dadvand, Durham, NC (US)

(21) Appl. No.: 18/405,721

(22) Filed: Jan. 5, 2024

(51) Int. Cl. H01L 23/00

(52) U.S. Cl. CPC H01L 24/05; H01L 24/92; H01L 24/06; H01L 24/32; H01L 24/45; H01L 24/48; H01L 24/73; H01L 2224/05166; H01L 2224/05601; H01L 2224/05609; H01L 2224/05611; H01L 2224/05618; H01L 2224/05624; H01L 2224/05638; H01L 2224/05639; H01L 2224/05644; H01L 2224/05647; H01L 2224/05649; H01L 2224/05655; H01L 2224/0566; H01L 2224/05666; H01L 2224/05669; H01L 2224/0603; H01L 2224/06181; H01L 2224/32245; H01L 2224/45124; H01L 2224/45147; H01L 2224/48091; H01L 2224/48245; H01L 2224/73265; H01L 2224/92247; H01L 2924/01014; H01L 2924/01048; H01L 2924/0133; H01L 2924/10272; H01L 2924/1033; H01L 2924/10344; H01L 2924/12032; H01L 2924/13064; H01L 2924/13091

(57) ABSTRACT

Semiconductor device packages are provided. In one example, the semiconductor device package includes a submount. The semiconductor device package further includes one or more semiconductor die on the submount. The one or more semiconductor die include one or more metallization layers. In one example, the one or more metallization layers include a shape-memory metallization (SMM) structure.

### FIELD

The present disclosure relates generally to power semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example embodiment of the present disclosure is directed to a semiconductor device package. The semiconductor device package includes a submount and one or more semiconductor die on the submount. The one or more semiconductor die include one or more metallization layers. The one or more metallization layers include a shape-memory metallization (SMM) structure.

Another example embodiment of the present disclosure is directed to a semiconductor device. The semiconductor device includes a semiconductor die and a shape-memory metallization (SMM) structure on the semiconductor die.

Another example embodiment of the present disclosure is directed to a semiconductor device. The semiconductor device includes a semiconductor die and a metallization structure on the semiconductor die. The metallization structure includes a ternary nitinol alloy.

Another example embodiment of the present disclosure is directed to a method. The method includes providing a shape-memory metallization (SMM) structure on a semiconductor die. The SMM structure includes a nitinol alloy.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a perspective view of a semiconductor device including a metallization structure according to example embodiments of the present disclosure;

FIG. 2 depicts a cross-sectional view of an example metallization structure according to example embodiments of the present disclosure;

FIG. 3 depicts an example crystal structure of a metallization structure according to example embodiments of the present disclosure;

FIG. 4 depicts example metallization structures of a semiconductor device according to example embodiments of the present disclosure;

FIG. 5 depicts a cross-sectional view of an example semiconductor device including a metallization structure according to example embodiments of the present disclosure;

FIG. 6 depicts an example semiconductor package of a semiconductor device according to example embodiments of the present disclosure;

FIG. 7 depicts an example semiconductor package of a semiconductor device according to example embodiments of the present disclosure; and

FIG. 8 depicts an example method according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Discrete semiconductor packages have been developed that include a semiconductor die, such as a metal-oxide-semiconductor field-effect transistor (MOSFET), a Schottky diode, and/or a high electron mobility transistor (HEMT) devices. Such semiconductor packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Discrete semiconductor packages with Schottky diodes and/or HEMT devices may be employed in many of the same high-performance power applications described above for MOSFETs, sometimes in systems that also include discrete power packages of MOSFETs.

Example aspects of the present disclosure are directed to semiconductor device packages (e.g., discrete semiconductor packages and power modules) for use in semiconductor applications and other electronic applications. It should be understood that the terms “semiconductor device package” and “semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a MOSFET, such as a silicon carbide-based MOSFET. Additionally and/or alternatively, in some examples, the one or more semiconductor die may include a Schottky diode, such as a silicon carbide-based Schottky diode. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices for purposes of illustration and discussion. Those having ordinary skill in the art, using the disclosures provided herein, will understand that the power semiconductor package of the present disclosure may include other power semiconductor devices without deviating from the scope of the present disclosure, such as diodes (e.g., Schottky diodes, PiN diodes, etc.), insulated gate bipolar transistors, HEMTs, or other devices.

In some semiconductor packages, the one or more semiconductor die may be attached to a submount (e.g., lead frame) by a die-attach material disposed between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the semiconductor package may use wire bond(s) (e.g., aluminum wire bond(s)) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The semiconductor package may further include a housing in which the one or more semiconductor die may be disposed. The semiconductor package may also include one or more electrical leads extending from the housing. More particularly, in some examples, the housing may be an encapsulating portion (e.g., epoxy mold compound (EMC)) formed around at least a portion of the submount and the one or more semiconductor die.

The one or more semiconductor die may further include one or more metallization structures. A “metallization structure” is any layer, structure, or other portion of a semiconductor device, semiconductor die, or semiconductor package, that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more contacts, interconnections, bonding pads, backside layers, metal layers, or metal coatings of the semiconductor device.

Power semiconductor devices may experience anomalies and/or failures resulting from the deformation, delamination, shifting, moving (e.g., glacial moving) of copper and/or aluminum metallization structures (including copper-aluminum alloys). In addition, cracks in a passivation layer of the power semiconductor device may result from thermomechanical stress to a semiconductor die surface during different reliability tests, such as thermal cycling (TC) tests. A coefficient of thermal expansion (CTE) mismatch between the EMC of the encapsulating portion and different parts of a semiconductor die, as well as the high temperature flexural modulus of EMC of the encapsulating portion, may induce a shear stress from the edges to the center of the semiconductor die, leading to deformation, delamination, and/or ratcheting of metallization structures. Similarly, the CTE mismatch between the semiconductor die metallization and other layers beneath and/or adjacent to the metallization structure may induce a biaxial thermomechanical stress, leading to plastic deformation and/or wrinkling, and ratcheting, of metallization structures during each TC cycle. This may consequently provide stress on the underlying and/or adjacent passivation layer and may ultimately induce defects or cracks in the passivation layer.

In some power semiconductor device packages, an aluminum-copper alloy has been introduced as an alternative metallization material for metallization structures relative to aluminum. The aluminum-copper alloy may exhibit slightly higher resistance to metal deformation as well as higher resistance to metal corrosion in the presence of ionic impurities. However, metallization structures based on an aluminum-copper alloy may suffer from residual stress, thermal stress relaxation, and accelerated galvanic corrosion of aluminum, particularly at an interface with a connection structure such as a wire bond. Moreover, the CTE mismatch between the metallization structure and other parts of semiconductor die, including a silicon nitride passivation layer or other passivation layer, is still of concern.

Aluminum-copper alloy is also vulnerable to damage in high power wire-bonding processes where a thick aluminum wire (e.g., 15 mil or 20 mil) or copper wire is used to achieve higher ampacity. This may induce further damage to the semiconductor die. The damage may be even more pronounced with bonding pads having a smaller thickness (e.g., about 4 μm). Increased metallization pad thickness (e.g., about 5 μm to about 6 μm), on the other hand, may have adverse effects such as risk of metal migration. Moreover, the diffusion of copper to the semiconductor die when an aluminum copper alloy is used for metallization structure may cause reliability concerns.

Accordingly, example aspects of the present disclosure provide semiconductor devices and semiconductor device packages having a semiconductor die and a metallization structure, such as a shape-memory metallization (SMM) structure, on the semiconductor die. The metallization structure includes a metal alloy, such as a shape-memory alloy (SMA), that has an alloy composition allowing the metallization structure to substantially recover its original shape and form after thermomechanical stress-related deformation. More particularly, SMAs can substantially recover their original form and shape through heating to a corresponding critical transformation temperature (CTT), which is determined by the alloy composition of the SMA that is used. Thus, by using SMAs having a CTT that is similar to the thermal cycling temperature (e.g., a range of about 100° C. to about 300° C.), example aspects of the present disclosure provide a semiconductor device with a shape-memory metallization (SMM) structure (e.g., contact, interconnect, bonding pad, etc.) that recovers its initial shape and form, thereby reducing the anomalies and/or failures discussed above (e.g., resulting from deformation, delamination, shifting, moving, etc.). For instance, in some examples, the SMM structure may have a CTT in a range of about 100° C. to about 300° C., such as about 125° C. to about 175° C.

For instance, an SMM structure (e.g., approximately 4 μm thick) may be used to replace the traditional metallization structures discussed above (e.g., Al, Cu, AlCu). Additionally and/or alternatively, an SMM structure (e.g., approximately 1 μm thick) may be deposited beneath and/or above the main metallization layer to force a recovery of minor deformation and/or wrinkling that is induced during each TC cycle. In this manner, SMM structures according to the present disclosure may mitigate/reduce the anomalies and/or failures resulting from the deformation, delamination, shifting, moving (e.g., glacial moving) of the traditional structures discussed above.

As used herein, the term “alloy” refers to a mixture of metal elements. Furthermore, a “shape-memory metallization structure” or “SMM structure” refers to any metallization layer or metallization structure that includes an SMA.

As will be discussed in greater detail below, in some examples, the semiconductor device may include a metallization structure that includes a nickel-titanium (“nitinol”) alloy. Nitinol alloys have unique properties, such as, in some examples, shape-memory effect and/or superelasticity. Moreover, nitinol alloys have unique reversible martensitic phase transformation properties that cause nitinol alloy-based metallization structures to form an SMM structure. More particularly, in a reversible crystal transformation, the transformation process does not involve atomic diffusion. Rather, all of the atoms in nitinol shift at the same time to form a new crystal structure. Put differently, due to the absence of atomic diffusion, the local alloy composition of nitinol is not altered during the crystal transformation process.

As used herein, “shape-memory” refers to the ability of an element and/or alloy to undergo deformation at a certain temperature and then recover about 90% of its original form and shape upon heating above its corresponding CTT and subsequent cooling. Furthermore, as used herein, “superelasticity” refers to an elastic response in an element and/or alloy that occurs in response to an applied stress.

In some examples, the nitinol alloy may be a ternary nitinol alloy. Ternary nitinol alloys may include nickel, titanium, and a ternary element. The mechanical and/or electrical properties of the metallization structure (e.g., SMM structure) may be controlled and/or tuned by the ratio of ternary element to the other metals in the metallization structure (e.g., nickel, titanium). For instance, an SMM structure with a ternary nitinol alloy according to the present disclosure may include a range of about 18% nickel to about 46% nickel, a range of about 2% to 32% ternary element to about 30% ternary element, and a range of about 49% titanium to about 52% titanium.

The mechanical and/or electrical properties of the metallization structure (e.g., SMM structure) may be further controlled and/or tuned by the type of ternary element used in relation to the other metals in the metallization structure (e.g., nickel, titanium). For instance, in some examples, the ternary element may be palladium (Pd); in such examples, the ternary nitinol alloy (NiPdTi) may include a range of about 5% palladium to about 30% palladium, such as a range of about 20% palladium to about 24% palladium. Additionally and/or alternatively, in some examples, the ternary element may be platinum (Pt); in such examples, the ternary nitinol alloy (NiPtTi) may include a range of about 5% platinum to about 30% platinum, such as a range of about 10% platinum to about 12% platinum. Additionally and/or alternatively, in some examples, the ternary element may be gold (Au); in such examples, the ternary nitinol alloy (NiAuTi) may include a range of about 5% gold to about 30% gold, such as a range of about 18% gold to about 20% gold.

Aspects of the present disclosure provide a number of technical effects and benefits. For instance, metallization structures according to examples of the present disclosure may address different reliability challenges in high performance semiconductor packaging, such as aluminum splash out, pad cratering, galvanic corrosion, passivation layer cracks, and the shift or deformation of metallization structures. Furthermore, such metallization structures may exhibit similar CTE values to that of different parts of the semiconductor die, while being resistant to the mechanical stresses posed by, for instance, the encapsulating material (e.g., EMC) of the semiconductor device package. Moreover, due to improved structural robustness of such metallization structures, these alloys may increase the reliability of wire bonding processes and may allow for the reduction in thickness of the metallization structure (e.g., thickness of the bonding pads) without risk of damaging the underlying layers in the semiconductor die during a wire bonding process. Even further, by using an SMA (e.g., NiPdTi, NiPtTi, NiAuTi), metallization structures according to the present disclosure may recover their original shape and form upon heating to the CTT.

In contrast to power semiconductor device packages that use, e.g., aluminum-based, copper-based, and/or aluminum-copper alloy-based metallization structures, semiconductor device packages according to the present disclosure may include metallization structures (e.g., SMM structures) having a stress-free high CTT (e.g., 100° C.-300° C.). By replacing the traditional aluminum-based and/or copper-based metallization structures with the metallization structures of the present disclosure, the anomalies and/or failures resulting from the deformation, delamination, shifting, moving (e.g., glacial moving) of the traditional copper and/or aluminum metallization structures may be mitigated. Furthermore, such SMM structures also reduce the failures during testing of the semiconductor device.

In some examples, the metallization structures may include an SMA, such as a ternary nitinol alloy. Such metallization structures may have excellent self-heating properties and may also possess high microstructural stability, as well as oxidation and corrosion resistance properties. The ternary nitinol alloys disclosed herein also provide greater microstructural stability than traditional nitinol alloys at high temperatures, as well as high thermomechanical fatigue life and strain recovery under different mechanical and temperature-induced deformation conditions.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material) may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material) may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

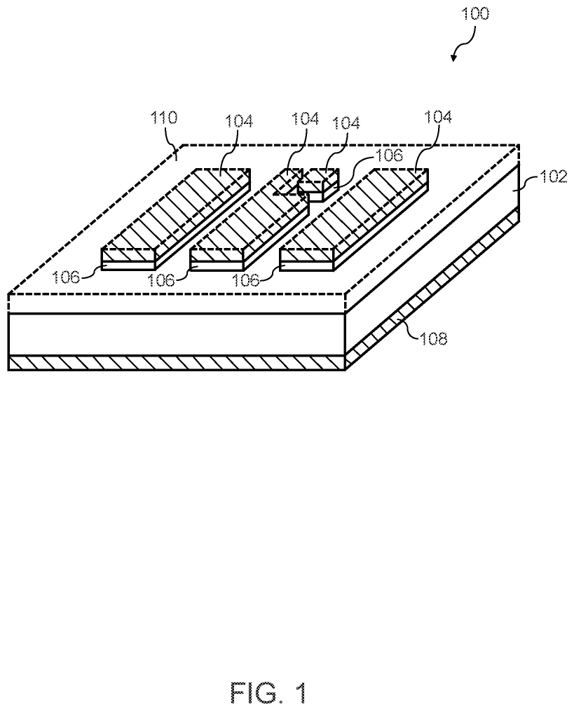

FIG. 1 depicts an example semiconductor device 100 according to example embodiments of the present disclosure. The semiconductor device 100 may include, for instance, one or more semiconductor die 102. The one or more semiconductor die 102 may include a wide bandgap semiconductor, such as a silicon carbide and/or a Group-III nitride (e.g., GaN, AlGaN, etc.). For instance, the one or more semiconductor die 102 may include one or more silicon carbide-based MOSFETs, one or more silicon carbide-based Schottky diodes, one or more Group-III nitride-based HEMTs, etc. The one or more semiconductor die 102 may include one or more epitaxial layers formed on a substrate, such as a silicon carbide substrate.

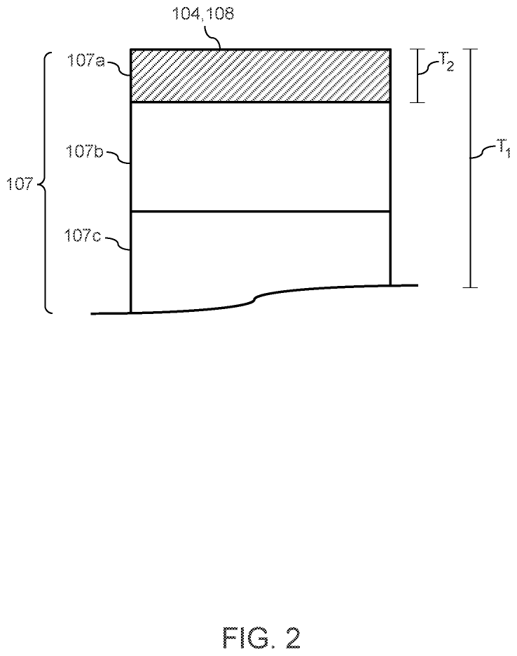

The semiconductor device 100 may include one or more metallization structures on one or more metallization layers 107 (FIG. 2) of the semiconductor die 102. The one or more metallization structures may include, for instance, bonding pads 104. Bonding pads 104 may be used to make an electrical connection to the semiconductor device 100 using connection structures, such as wire bonds. The bonding pads 104 may be disposed on an adhesion layer 106 to secure the bonding pads 104 to the one or more semiconductor die 102 to provide, for instance, a gate connection, source connection, kelvin connection, sensor connection, or other suitable connection. The adhesion layer 106 may be, for instance, titanium. The bonding pads 104 may have a thickness of about 4 microns (4 μm) or less in some embodiments.

In some examples, the semiconductor device 100 may include a backside metallization structure 108 on the one or more semiconductor die 102. In some semiconductor packages, the backside metallization structure 108 may be secured to a submount (e.g., a lead frame of a semiconductor package) using, for instance, a die-attach material to provide a thermal and/or electrical connection for the semiconductor device 100 (e.g., a drain connection). More particularly, in some examples, the submount may include copper. For instance, the submount may include a direct bonded copper (DBC) substrate, an active metal brazed (AMB) substrate, and/or other power substrate. Furthermore, the die-attach material may include a sintered material, such as sintered silver or sintered copper. In this manner, the one or more semiconductor die 102 may be on the submount.

The semiconductor device 100 may include a passivation layer 110. The bonding pads 104 may be exposed through openings in the passivation layer 110. The passivation layer 110 may include one or more suitable passivation materials, such as silicon nitride. In some examples, the passivation layer 110 may be a polymer, such as polyimide. In some examples, the passivation layer 110 may be SiO₂, MgOx, MgNx, ZnO, SiNx, SiOx, or other dielectric material.

According to example embodiments of the present disclosure, the one or more metallization structures (e.g., bonding pads 104 and/or the backside metallization structure 108) may include a shape-memory alloy (SMA). Hence, in some examples, the one or more metallization structures may be one or more shape-memory metallization (SMM) structures that may recover their original form and shape through heating a corresponding critical transformation temperature (CTT) and subsequent cooling.

In some examples, the semiconductor device 100 may include a plurality of metallization layers. By way of non-limiting example, referring briefly to FIG. 2, a cross-sectional view of a plurality of metallization layers 107 is depicted according to example embodiments of the present disclosure. As shown, the plurality of metallization layers 107 may include a first metallization layer 107A, a second metallization layer 107B, and a third metallization layer 107C. The plurality of metallization layers 107 may have a combined thickness T1 of about 4 microns (4 μm) or less in some embodiments. It should be understood that the plurality of metallization layers 107 is depicted with three metallization layers (e.g., layers 107A-107C) for purposes of illustration and discussion. Those having ordinary skill in the art, using the disclosures provided herein, will understand that the plurality of metallization layers 107 may include more, or fewer, than three layers without deviating from the scope of the present disclosure.

In some examples, such as that depicted in FIG. 2, at least one metallization layer 107A-107C of the plurality of metallization layers 107 may be an SMM layer that includes one or more of the SMM structures described herein. For instance, as shown, the first metallization layer 107A may include an SMA, and the second metallization 107B and third metallization layer 107C may include other non-SMA alloys. Thus, the first metallization layer 107A may be an SMM layer and may include the one or more SMM structures, such as bonding pads 104 and/or backside metallization structure 108. The SMM layer (e.g., first metallization layer 107A) may have a thickness T2 of about 1 micron (1 μm) or less in some embodiments.

The plurality of metallization layers 107 is depicted in FIG. 2 with only one SMM layer (e.g., first metallization layer 107A) for purposes of illustration and discussion. Those having ordinary skill in the art, using the disclosures provided herein, will understand that the plurality of metallization layers 107 may include more than one SMM layer without deviating from the scope of the present disclosure. For instance, in some examples, each metallization layer 107A-107C of the plurality of metallization layers 107 may include an SMA and, as such, may be an SMM layer. In such examples, each of the plurality of SMM layers (e.g., metallization layers 107A-107C) may include the same SMA and/or may include different SMAs. Furthermore, as noted above, the plurality of SMM layers (e.g., metallization layers 107A-107C) may have a combined thickness T1 of about 4 microns (4 μm) or less in some embodiments.

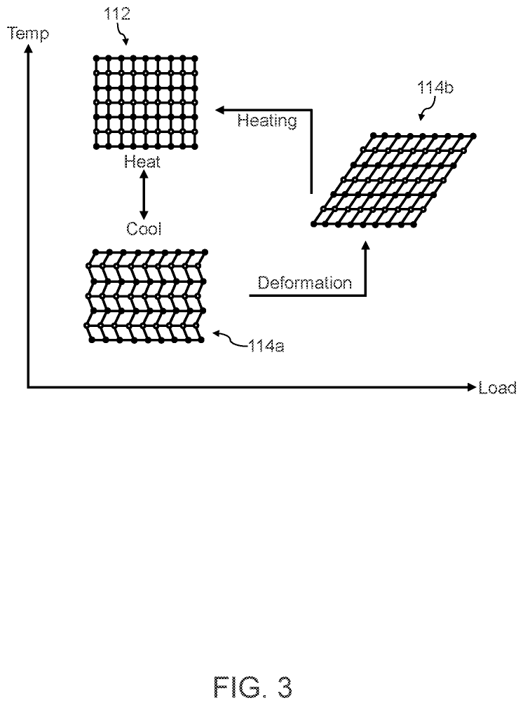

Referring briefly to FIG. 3, an example crystal structure of a metallization structure is depicted according to example embodiments of the present disclosure. More particularly, FIG. 3 depicts an example crystal structure of a shape-memory metallization (SMM) structure that includes a shape-memory alloy (SMA), such as a nitinol alloy. As noted above, SMAs are metals that may, in some examples, exhibit properties such as shape-memory effect and/or superelasticity. More particularly, SMAs may undergo large amounts of strain and/or stress and then, after a temperature increase to a corresponding CTT and subsequent cooling, may revert back to and retain about 90% of its original shape and form. For instance, by way of non-limiting example, one such SMA is a nickel-titanium alloy (e.g., NiTi alloy). Nickel-titanium alloys are also referred to as “nitinol alloys” and, as such, are referred to herein as “nitinol alloys.”

Phase transformations may be induced by a temperature change or an applied stressor. More particularly, due to changes in temperature and/or mechanical strain, nitinol alloys may include an austenitic phase (e.g., austenite 112) and a martensitic phase (e.g., martensite 114), which manifest as changes to the crystal structure with the application of stress and/or heat. More particularly, as shown in FIG. 3, austenite 112 has a body center cubic (BCC) crystal structure and is stable at higher temperatures. Conversely, martensite 114 has a monoclinic crustal structure and is stable at lower temperatures. Furthermore, nitinol alloys have a unique property of reversible martensitic phase transformation which allows nitinol alloys to form SMM structures that may recover to and retain approximately 90% of its original shape and form by heating to its CTT and subsequently cooling.

The martensitic phase of nitinol alloys include a twinned martensite 114A crystal structure and a deformed martensite 114B crystal structure. More particularly, in its original (e.g., undeformed) condition, nitinol alloys exist as twinned martensite 114A. In twinned martensite 114A, martensite variants are arranged in a twin relationship, where each variant is a “mirror image” of its “twin” across a crystallographic plane. Furthermore, this “twin relationship” microstructure allows nitinol alloys to exhibit superelastic properties. When an external load is applied to twinned martensite 114A, the martensite is deformed, thereby producing deformed martensite 114B. More particularly, this transformation is known as “displacive transformation” and/or “plastic deformation,” which involves a rearrangement of atoms into a more stable crystal structure without any change in volume.

As shown in FIG. 3, by applying heat to the nitinol alloy, the deformed martensite 114B transforms back to austenite 112 which, as noted above, has a BCC crystal structure. Subsequently, following cooling, austenite 112 transforms back to twinned martensite 114A. Put differently, when deformed martensite 114B transforms back to twinned martensite 114A (via austenite 112), the nitinol alloy may recover its original shape and form. In this manner, nitinol alloys have a “shape-memory” property, thereby allowing metallization structures having nitinol alloys to be SMM structures.

It should be understood that SMAs and SMMs are discussed herein with reference to nitinol alloys for purposes of illustration and discussion. Those having ordinary skill in the art, using the disclosures provided herein, will understand that any suitable SMA may be used without deviating from the scope of the present disclosure. For instance, by way of non-limiting examples, SMM structures may include any suitable SMA, such as a silver-cadmium alloy (e.g., AgCd alloy), a gold-cadmium alloy (e.g., AuCd alloy), a copper-aluminum-nickel alloy (e.g., CuAlNi alloy), a copper-tin alloy (e.g., CuSn alloy), a copper-zinc alloy (e.g., CuZn alloy), a copper-zinc-silicon alloy (e.g., CuZnSi alloy), a copper-zinc-tin alloy (e.g., CuZnSn alloy), a copper-zinc-aluminum alloy (e.g., CuZnAl alloy), an indium-titanium alloy (e.g., InTi alloy), a nickel-aluminum alloy (e.g., NiAl alloy), an iron-platinum alloy (e.g., FePt alloy), a manganese-copper alloy (e.g., MnCu alloy), an iron-manganese alloy (e.g., FeMn alloy), and/or an iron-manganese-silicon alloy (e.g., FeMnSi alloy).

Referring again to FIG. 1, the one or more metallization structures (e.g., bonding pads 104 and/or the backside metallization structure 108) may include an SMA such as, for instance, a nitinol alloy. For instance, the bonding pads 104 and/or the backside metallization structure 108 may include a ternary nitinol alloy. More particularly, the ternary nitinol alloy may include nickel, titanium, and a ternary element. In some examples, the ternary nitinol alloy may include a range of about 18% nickel to about 46% nickel, such as a range of about 21% nickel to about 43% nickel. Furthermore, the ternary nitinol alloy may include a range of about 49% titanium to about 52% titanium, such as approximately 50% titanium. Even further, the ternary nitinol alloy may include a range of about 5% ternary element to about 30% ternary element.

In some examples, the ternary element may include palladium (Pd). For instance, the ternary nitinol alloy may include a range of about 5% palladium to about 30% palladium, such as about 20% palladium to about 24% palladium. Hence, the metallization structure may include a nickel-palladium-titanium alloy (e.g., NiPdTi).

In some examples, the ternary element may include platinum (Pt). For instance, the ternary nitinol alloy may include a range of about 5% platinum to about 30% platinum, such as about 10% platinum to about 12% platinum. Hence, the metallization structure may include a nickel-platinum-titanium alloy (e.g., NiPtTi).

In some examples, the ternary element may include gold (Au). For instance, the ternary nitinol alloy may include a range of about 5% gold to about 30% gold, such as about 18% gold to about 20% gold. Hence, the metallization structure may include a nickel-gold-titanium alloy (e.g., NiAuTi).

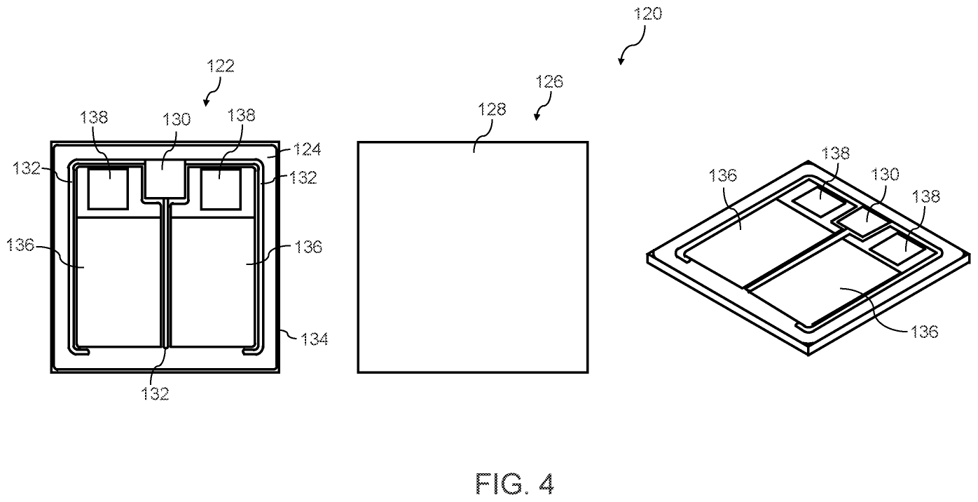

FIG. 4 depicts example metallization layers of a semiconductor device 120 according to example embodiments of the present disclosure. FIG. 4 is intended to represent structures for identification and description and is not intended to represent the structures to physical scale. More particularly, as shown, the semiconductor device 120 includes a topside metallization layer 122 on a semiconductor die 124. The semiconductor device 120 may also include a backside metallization layer 126. The backside metallization layer 126 may include a drain pad 128 on the backside of the semiconductor die 124. The semiconductor die 124 may include one or more wide band gap semiconductor materials and may include doping and/or different epitaxial layer structures to form one or more active semiconductor cells for semiconductor devices (e.g., silicon carbide-based MOSFETs, silicon carbide-based Schottky diodes, Group III-nitride based HEMTs, etc.). The semiconductor die 124 may include one or more epitaxial layers formed on a substrate, such as a silicon carbide substrate.

The topside metallization layer 122 may include metallization structures including a gate pad 130, gate runners 132, an edge termination structure 134, source pads 136, and/or additional bond pads 138 (e.g., source kelvin bond pads or sensor bond pads). The plurality of gate runners 132 (e.g., gate buses) may extend from the gate pad 130 to better distribute a gate signal to the outer edges and to the middle of the power semiconductor device 120. The edge termination structure 134 may be around the perimeter of the semiconductor device 120 to buffer an electric field so that voltage over distance is reduced.

The metallization layer 122 may include metallized pads (e.g., the gate pad 130 and source pads 136) for power and signal connection to other components (e.g., submounts, lead frames, terminals, etc.) so that the metallization layer 122 acts as a bonding layer for the semiconductor device 120. The gate pad 130 and/or the source pads 136 may have a thickness of 4 microns (4 μm) or less. Signal connections to the gate pad 130 may be implemented, for instance, using wire bond(s). The source pads 136 may be directly on the active region of the semiconductor die 124. A power connection may be made to the source pads 136 using a clip or similar attach which is directly soldered, sintered, welded to the source pads 136. The source pads 136 may serve as source contact(s) or other contacts (e.g., ohmic contacts, Schottky contacts, etc.) for the semiconductor cells in the active region(s) of the semiconductor die 124 of the semiconductor device 140.

The semiconductor device 120 may include additional bonding pads 138 (e.g., for connection to wire bonds or other connection structure). The additional bonding pads 138 may be used, for instance, for source kelvin connection(s) and/or sensor connections for the semiconductor device 120.

According to example embodiments of the present disclosure, at least a portion of one or more of the metallization structures of FIG. 4, including at least a portion of one or more of the gate pad 130, gate runners 132, edge termination structure 134, source pads 136, additional bond pads 138, and/or the drain attach pad 128, may include an SMA, such as a nitinol alloy. As such, the gate pad 130, gate runners 132, edge termination structure 134, source pads 136, additional bond pads 138, and/or the drain attach pad 128 may be SMM structures.

For instance, in some examples, at least a portion of one or more of the gate pad 130, gate runners 132, edge termination structure 134, source pads 136, additional bond pads 138, and/or the drain attach pad 128 may include a ternary nitinol alloy. More particularly, the ternary nitinol alloy may include nickel, titanium, and a ternary element. In some examples, the ternary nitinol alloy may include a range of about 18% nickel to about 46% nickel, such as a range of about 21% nickel to about 43% nickel. Furthermore, the ternary nitinol alloy may include a range of about 49% titanium to about 52% titanium, such as approximately 50% titanium. Even further, the ternary nitinol alloy may include a range of about 5% ternary element to about 30% ternary element.

In some examples, the ternary element may include palladium (Pd). For instance, the ternary nitinol alloy may include a range of about 5% palladium to about 30% palladium, such as about 20% palladium to about 24% palladium. Hence, the metallization structure may include a nickel-palladium-titanium alloy (e.g., NiPdTi).

In some examples, the ternary element may include platinum (Pt). For instance, the ternary nitinol alloy may include a range of about 5% platinum to about 30% platinum, such as about 10% platinum to about 12% platinum. Hence, the metallization structure may include a nickel-platinum-titanium alloy (e.g., NiPtTi).

In some examples, the ternary element may include gold (Au). For instance, the ternary nitinol alloy may include a range of about 5% gold to about 30% gold, such as about 18% gold to about 20% gold. Hence, the metallization structure may include a nickel-gold-titanium alloy (e.g., NiAuTi).

It should be understood that the metallization layers of FIG. 4 are discussed with reference to nitinol alloys for purposes of illustration and discussion. Those having ordinary skill in the art, using the disclosures provided herein, will understand that any suitable SMA may be used without deviating from the scope of the present disclosure. For instance, by way of non-limiting examples, SMM structures may include any suitable SMA, such as a silver-cadmium alloy (e.g., AgCd alloy), a gold-cadmium alloy (e.g., AuCd alloy), a copper-aluminum-nickel alloy (e.g., CuAlNi alloy), a copper-tin alloy (e.g., CuSn alloy), a copper-zinc alloy (e.g., CuZn alloy), a copper-zinc-silicon alloy (e.g., CuZnSi alloy), a copper-zinc-tin alloy (e.g., CuZnSn alloy), a copper-zinc-aluminum alloy (e.g., CuZnAl alloy), an indium-titanium alloy (e.g., InTi alloy), a nickel-aluminum alloy (e.g., NiAl alloy), an iron-platinum alloy (e.g., FePt alloy), a manganese-copper alloy (e.g., MnCu alloy), an iron-manganese alloy (e.g., FeMn alloy), and/or an iron-manganese-silicon alloy (e.g., FeMnSi alloy).

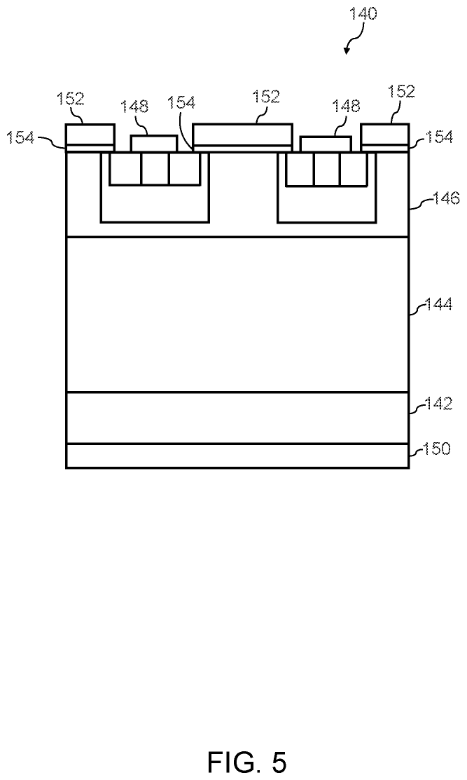

FIG. 5 depicts a cross-sectional schematic view of an example semiconductor device 140 including a metallization structure according to example embodiments of the present disclosure. FIG. 5 is intended to represent structures for identification and description and is not intended to represent the structures to physical scale. The semiconductor device 140 shown in FIG. 5, in some examples, may be a unit cell of an active semiconductor cell of the semiconductor device 100 described above with reference to FIG. 1. For instance, in some examples, the semiconductor device 140 may be on a semiconductor die of the one or more semiconductor die 102 discussed above with reference to FIG. 1.

As shown, the semiconductor device 140 may include one or more wide bandgap semiconductor materials, such as wide bandgap semiconductor substrate 142. The semiconductor device 140 may further include doping and/or different epitaxial layer structures, such as drift region 144 and spreading layer 146, formed on the substrate 142. In this manner, the semiconductor device 140 may include one or more wide bandgap semiconductor devices, such as silicon carbide-based MOSFETs, silicon carbide-based Schottky diodes, Group-III nitride-based HEMTs, and the like.

The semiconductor device 140 may include one or more metallization structures, such as contacts for the semiconductor device 140. In the example shown in FIG. 5, the one or more metallization structures may include a source contact 148, a drain contact 150, and/or a gate contact 152. A gate dielectric layer 154 (e.g., silicon dioxide) may be disposed between the gate contact 152 and the spreading layer 146. The semiconductor device 140 may further include one or more passivation layers (e.g., silicon nitride layers, polyimide layers, etc.), which are not illustrated in FIG. 5 for simplicity of illustration.

According to example embodiments of the present disclosure, at least a portion of one or more of the metallization structures of the semiconductor device 140 depicted in FIG. 5—including at least a portion of the source contacts 148, drain contacts 150, and gate contacts 152—may include an SMA, such as a nitinol alloy. As such, the metallization structures of FIG. 5 (e.g., source contacts 148, drain contacts 150, and/or gate contacts 152) may be SMM structures. In some examples, the metallization layers of FIG. 5 may directly contact an encapsulating portion (not shown) of the semiconductor device 140.

For instance, in some examples, at least a portion of the metallization structures of semiconductor device 140 may include a ternary nitinol alloy. More particularly, the ternary nitinol alloy may include nickel, titanium, and a ternary element. In some examples, the ternary nitinol alloy may include a range of about 18% nickel to about 46% nickel, such as a range of about 21% nickel to about 43% nickel. Furthermore, the ternary nitinol alloy may include a range of about 49% titanium to about 52% titanium, such as approximately 50% titanium. Even further, the ternary nitinol alloy may include a range of about 5% ternary element to about 30% ternary element.

In some examples, the ternary element may include palladium (Pd). For instance, the ternary nitinol alloy may include a range of about 5% palladium to about 30% palladium, such as about 20% palladium to about 24% palladium. Hence, the metallization structure may include a nickel-palladium-titanium alloy (e.g., NiPdTi).

In some examples, the ternary element may include platinum (Pt). For instance, the ternary nitinol alloy may include a range of about 5% platinum to about 30% platinum, such as about 10% platinum to about 12% platinum. Hence, the metallization structure may include a nickel-platinum-titanium alloy (e.g., NiPtTi).

In some examples, the ternary element may include gold (Au). For instance, the ternary nitinol alloy may include a range of about 5% gold to about 30% gold, such as about 18% gold to about 20% gold. Hence, the metallization structure may include a nickel-gold-titanium alloy (e.g., NiAuTi).

It should be understood that the metallization layers of FIG. 5 are discussed with reference to nitinol alloys for purposes of illustration and discussion. Those having ordinary skill in the art, using the disclosures provided herein, will understand that any suitable SMA may be used without deviating from the scope of the present disclosure. For instance, by way of non-limiting examples, SMM structures may include any suitable SMA, such as a silver-cadmium alloy (e.g., AgCd alloy), a gold-cadmium alloy (e.g., AuCd alloy), a copper-aluminum-nickel alloy (e.g., CuAlNi alloy), a copper-tin alloy (e.g., CuSn alloy), a copper-zinc alloy (e.g., CuZn alloy), a copper-zinc-silicon alloy (e.g., CuZnSi alloy), a copper-zinc-tin alloy (e.g., CuZnSn alloy), a copper-zinc-aluminum alloy (e.g., CuZnAl alloy), an indium-titanium alloy (e.g., InTi alloy), a nickel-aluminum alloy (e.g., NiAl alloy), an iron-platinum alloy (e.g., FePt alloy), a manganese-copper alloy (e.g., MnCu alloy), an iron-manganese alloy (e.g., FeMn alloy), and/or an iron-manganese-silicon alloy (e.g., FeMnSi alloy).

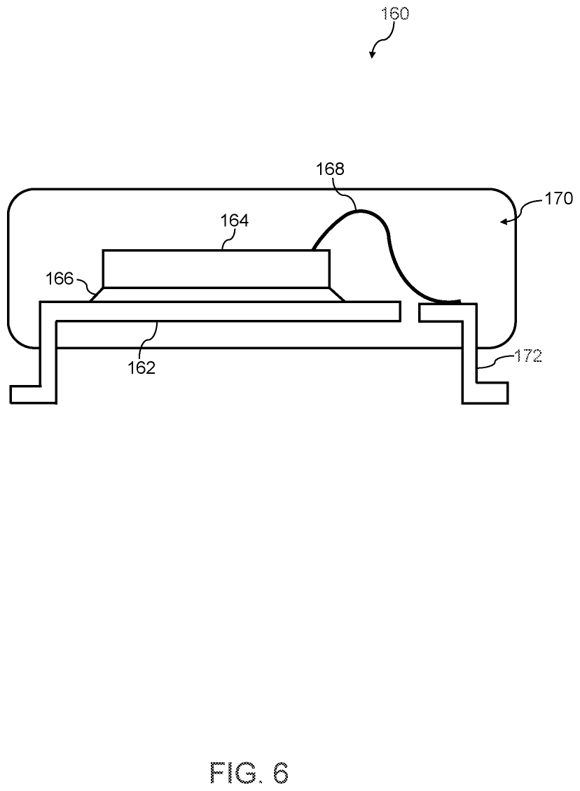

FIG. 6 depicts an example semiconductor package 160 of a semiconductor device according to example embodiments of the present disclosure. The semiconductor package 160 may be, for instance, a discrete semiconductor package. FIG. 6 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 6 is intended to represent structures for identification and description and is not intended to represent the structures to physical scale.

As shown, the semiconductor package 160 may include a conductive submount 162 (e.g., a patterned conductive substrate, lead frame, clip structure or other power substrate) on which a semiconductor die 164 containing one or more power devices (e.g., transistors, diodes, etc.) is attached using a die-attach material 166. The die-attach material 166 may provide a thermal, mechanical, and electrical connection between the semiconductor die 164 and the conductive submount 162. In some examples, the semiconductor die 164 may also be connected to the conductive submount 162 using wire bonds 168. An encapsulating material 170 (e.g., epoxy mold compound (EMC)) may fill the space around the semiconductor die 164 and the submount 162, thereby forming a housing. The semiconductor package 160 may further include one or more electrical leads 172 that extend outward from the housing (e.g., outward from the encapsulating material 170).

The semiconductor package 160 may include one or more metallization structures, such as any of the metallization structures disclosed herein. More particularly, the semiconductor die 164 may include one or more metallization structures, such as bonding pads (e.g., bonding pads 104 (FIG. 1), bonding pads 138 (FIG. 4), etc.). The bonding pads may be coupled to the one or more electrical leads 172 using the wire bonds 168. The wire bonds 168 may be aluminum and/or copper. The wire bonds 168 may have a thickness of about 15 mil to about 20 mil (e.g., about 381 μm to about 508 μm). As noted above, the bonding pads may have a thickness, for instance, of about 4 μm or less. A backside metallization layer (e.g., backside metallization layer 108 (FIG. 1), backside metallization layer 126 (FIG. 4)) on the semiconductor die 164 may be coupled to the submount 162 (e.g., lead frame) using, for instance, the die-attach material 166. The encapsulating material 170 may encapsulate the semiconductor die 164, including its metallization structures, wire bonds 168, submount 162, and other portions of the semiconductor package 160. In some examples, the encapsulating material 170 may directly contact the metallization structures (e.g., bonding pads, backside metallization layer, etc.) of the semiconductor package 160.

According to example embodiments of the present disclosure, at least a portion of one or more of the metallization structures of the semiconductor package 160 depicted in FIG. 6 may include an SMA, such as a nitinol alloy. As such, the semiconductor package 160 may include one or more SMM structures. In some examples, the encapsulating material 170 may directly contact the SMM structures (e.g., bonding pads, backside metallization layer, etc.).

For instance, in some examples, at least a portion of the metallization structures of semiconductor die 164 may include a ternary nitinol alloy. More particularly, the ternary nitinol alloy may include nickel, titanium, and a ternary element. In some examples, the ternary nitinol alloy may include a range of about 18% nickel to about 46% nickel, such as a range of about 21% nickel to about 43% nickel. Furthermore, the ternary nitinol alloy may include a range of about 49% titanium to about 52% titanium, such as approximately 50% titanium. Even further, the ternary nitinol alloy may include a range of about 5% ternary element to about 30% ternary element.

In some examples, the ternary element may include palladium (Pd). For instance, the ternary nitinol alloy may include a range of about 5% palladium to about 30% palladium, such as about 20% palladium to about 24% palladium. Hence, the metallization structure may include a nickel-palladium-titanium alloy (e.g., NiPdTi).

In some examples, the ternary element may include platinum (Pt). For instance, the ternary nitinol alloy may include a range of about 5% platinum to about 30% platinum, such as about 10% platinum to about 12% platinum. Hence, the metallization structure may include a nickel-platinum-titanium alloy (e.g., NiPtTi).

In some examples, the ternary element may include gold (Au). For instance, the ternary nitinol alloy may include a range of about 5% gold to about 30% gold, such as about 18% gold to about 20% gold. Hence, the metallization structure may include a nickel-gold-titanium alloy (e.g., NiAuTi).

It should be understood that the metallization layers of FIG. 6 are discussed with reference to nitinol alloys for purposes of illustration and discussion. Those having ordinary skill in the art, using the disclosures provided herein, will understand that any suitable SMA may be used without deviating from the scope of the present disclosure. For instance, by way of non-limiting examples, SMM structures may include any suitable SMA, such as a silver-cadmium alloy (e.g., AgCd alloy), a gold-cadmium alloy (e.g., AuCd alloy), a copper-aluminum-nickel alloy (e.g., CuAlNi alloy), a copper-tin alloy (e.g., CuSn alloy), a copper-zinc alloy (e.g., CuZn alloy), a copper-zinc-silicon alloy (e.g., CuZnSi alloy), a copper-zinc-tin alloy (e.g., CuZnSn alloy), a copper-zinc-aluminum alloy (e.g., CuZnAl alloy), an indium-titanium alloy (e.g., InTi alloy), a nickel-aluminum alloy (e.g., NiAl alloy), an iron-platinum alloy (e.g., FePt alloy), a manganese-copper alloy (e.g., MnCu alloy), an iron-manganese alloy (e.g., FeMn alloy), and/or an iron-manganese-silicon alloy (e.g., FeMnSi alloy).

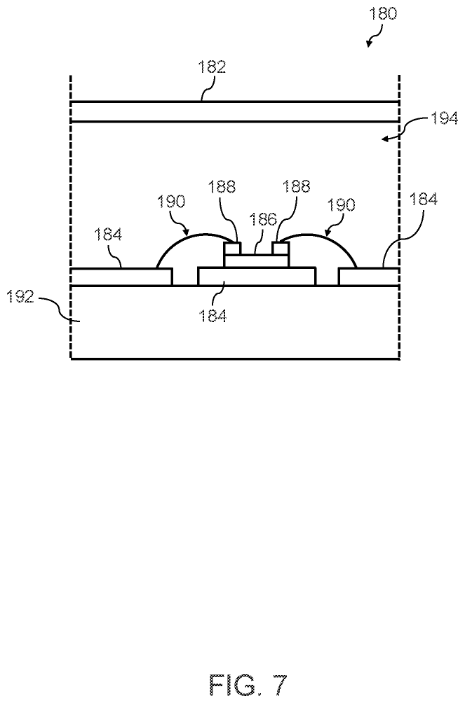

FIG. 7 depicts a cross-sectional view of an example semiconductor package of a semiconductor device 180 according to example embodiments of the present disclosure. The semiconductor device 180 of FIG. 7 is a portion of a power module. FIG. 7 is intended to represent structures for identification and description and is not intended to represent the structures to physical scale. The semiconductor device 180 may include a housing 182. The semiconductor device 180 may include a conductive submount 184 (e.g., a patterned conductive submount) on which a semiconductor die 186 is mounted (e.g., using a die-attach material). For instance, the semiconductor die 186 may be mounted on submount 184 using a die-attach material that includes a sintered material, such as sintered silver and/or sintered copper. The semiconductor die 186 may include one or more metallization structures, such as bonding pads 188. In some embodiments, the semiconductor die 186 may be connected to the conductive submount 184 using wire bonds 190. The conductive submount 184 may be mounted on a base layer 192 (e.g., an insulating layer). An inert gel 194 may fill the space between the semiconductor die 186 and the housing 182.

According to example embodiments of the present disclosure, at least a portion of one or more of the metallization structures of the semiconductor die 186 in FIG. 7, including at least a portion of one or more of the bonding pads 188 may include an SMA, such as a nitinol alloy. As such, the metallization structures of FIG. 7 may be SMM structures. In some examples, the inert gel 194 may directly contact the SMM structures (e.g., bonding pads 188).

For instance, in some examples, at least a portion of the metallization structures of semiconductor die 186 may include a ternary nitinol alloy. More particularly, the ternary nitinol alloy may include nickel, titanium, and a ternary element. In some examples, the ternary nitinol alloy may include a range of about 18% nickel to about 46% nickel, such as a range of about 21% nickel to about 43% nickel. Furthermore, the ternary nitinol alloy may include a range of about 49% titanium to about 52% titanium, such as approximately 50% titanium. Even further, the ternary nitinol alloy may include a range of about 5% ternary element to about 30% ternary element.

In some examples, the ternary element may include palladium (Pd). For instance, the ternary nitinol alloy may include a range of about 5% palladium to about 30% palladium, such as about 20% palladium to about 24% palladium. Hence, the metallization structure may include a nickel-palladium-titanium alloy (e.g., NiPdTi).

In some examples, the ternary element may include platinum (Pt). For instance, the ternary nitinol alloy may include a range of about 5% platinum to about 30% platinum, such as about 10% platinum to about 12% platinum. Hence, the metallization structure may include a nickel-platinum-titanium alloy (e.g., NiPtTi).

In some examples, the ternary element may include gold (Au). For instance, the ternary nitinol alloy may include a range of about 5% gold to about 30% gold, such as about 18% gold to about 20% gold. Hence, the metallization structure may include a nickel-gold-titanium alloy (e.g., NiAuTi).

It should be understood that the metallization layers of FIG. 7 are discussed with reference to nitinol alloys for purposes of illustration and discussion. Those having ordinary skill in the art, using the disclosures provided herein, will understand that any suitable SMA may be used without deviating from the scope of the present disclosure. For instance, by way of non-limiting examples, SMM structures may include any suitable SMA, such as a silver-cadmium alloy (e.g., AgCd alloy), a gold-cadmium alloy (e.g., AuCd alloy), a copper-aluminum-nickel alloy (e.g., CuAlNi alloy), a copper-tin alloy (e.g., CuSn alloy), a copper-zinc alloy (e.g., CuZn alloy), a copper-zinc-silicon alloy (e.g., CuZnSi alloy), a copper-zinc-tin alloy (e.g., CuZnSn alloy), a copper-zinc-aluminum alloy (e.g., CuZnAl alloy), an indium-titanium alloy (e.g., InTi alloy), a nickel-aluminum alloy (e.g., NiAl alloy), an iron-platinum alloy (e.g., FePt alloy), a manganese-copper alloy (e.g., MnCu alloy), an iron-manganese alloy (e.g., FeMn alloy), and/or an iron-manganese-silicon alloy (e.g., FeMnSi alloy).

FIGS. 6-7 depict example semiconductor packages for purposes of illustration and discussion. Those of ordinary skill in the art, using the disclosures provided herein, will understand that different semiconductor package configurations may be used without deviating from the scope of the present disclosure.

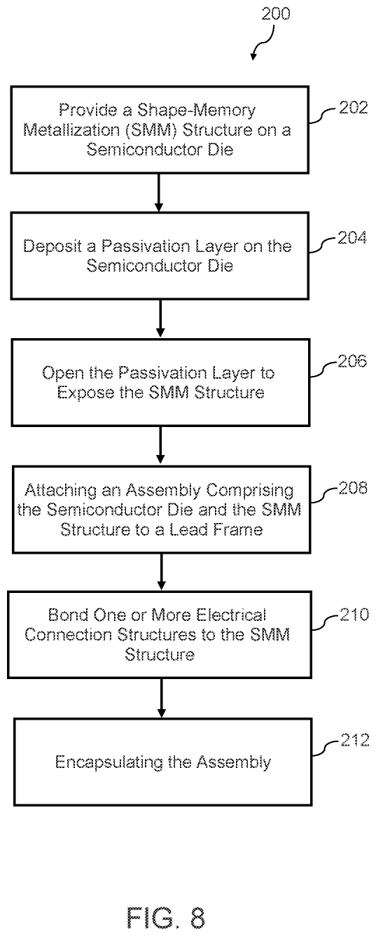

FIG. 8 depicts a flow chart of an example method 200 according to example embodiments of the present disclosure. FIG. 8 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 202, the method 200 includes providing a shape-memory metallization (SMM) structure on a semiconductor die, such as an SMM structure including a nitinol alloy (e.g., NiTi alloy). The semiconductor die may include one or more wide bandgap semiconductors. The semiconductor die may further include doping and/or different epitaxial layer structures to form one or more semiconductor devices (e.g., silicon carbide-based MOSFETs, silicon carbide-based Schottky diodes, Group-III nitride-based HEMTs, etc.). Furthermore, the SMM structure may be any of the metallization structures described herein. As one non-limiting example, the method 200 may include providing the metallization layers of FIG. 1 on the semiconductor die 102.

According to example embodiments of the present disclosure, at least a portion of the SMM structure may include a shape-memory alloy (SMA) (e.g., Ag—Cd, Au—Cd, CuAlNi, CuSn, CuZn, CuZnSi, CuZnSn, CuZnAl, InTi, NiAl, FePt, MnCu, FeMn, and/or FeMnSi alloys). As noted above, SMAs are metal alloys having an alloy composition that allows the SMM structure to be deformed and subsequently recover its original shape and form. More particularly, although thermomechanical stress may deform the SMM structure, the thermomechanical properties of the SMAs (e.g., shape-memory (SME) effect, superelasticity (SE)) allow the SMM structure to recover about 90% of its original (e.g., pre-deformation) shape and form following a temperature increase to a corresponding CTT and subsequent cooling.

In some examples, the SMM structure may include a nitinol (i.e., NiAl) alloy, such as a ternary nitinol alloy. The ternary nitinol alloy may include nickel, titanium, and a ternary element. In some examples, the ternary nitinol alloy may include a range of about 18% nickel to about 46% nickel, such as about 21% nickel to about 43% nickel; a range of about 49% titanium to about 52% titanium; and a range of about 5% ternary element to about 30% ternary element.

In some examples, the ternary element includes palladium. For instance, the ternary nitinol alloy may include a range of about 5% palladium to about 30% palladium, such as about 20% palladium to about 24% palladium. In some examples, the ternary element includes platinum. For instance, the ternary nitinol alloy may include a range of about 5% platinum to about 30% platinum, such as about 10% platinum to about 12% platinum. In some examples the ternary element includes gold. For instance, the ternary nitinol alloy may include a range of about 5% gold to about 30% gold, such as about 18% gold to about 20% gold.

At 204, the method 200 includes depositing a passivation layer on the semiconductor die. In some examples, the passivation layer may include silicon nitride. The passivation layer may include a polymer, such as polyimide. In some examples, the passivation layer may be SiO₂, MgOx, MgNx, ZnO, SiNx, SiOx, or other dielectric material. As an example, the passivation layer 110 may be deposited on the semiconductor die 102 of FIG. 1.

At 206, the method 200 includes opening the passivation layer to expose the SMM structure. For instance, the method may include opening the passivation layer 110 to expose the bonding pads 104 of FIG. 1.

At 208, the method 200 includes attaching an assembly including the semiconductor die and the SMM structure to a submount, such as a lead frame. For instance, the method may include attaching the backside metallization structure 108 of FIG. 1 to a submount (e.g., using a die-attach material).

At 210, the method 200 includes bonding one or more electrical connection structures, such as wire bond(s) and/or die-attach material(s), to the SMM structure. For instance, wire bonds may be bonded to the metallization structures of FIG. 1 (e.g., bonding pads 104).

At 212, the method 200 includes encapsulating the assembly, including the semiconductor die, the SMM structure, and/or the passivation layer. For instance, the assembly may be encapsulated with an EMC.

Example aspects of the present disclosure are set forth below. Any of the below features or examples may be used in combination with any of the embodiments or features provided in the present disclosure.

One example embodiment of the present disclosure is directed to a semiconductor device package. The semiconductor device package includes a submount and one or more semiconductor die on the submount. The one or more semiconductor die include one or more metallization layers. The one or more metallization layers include a shape-memory metallization (SMM) structure.

In some examples, the semiconductor device package further includes an encapsulating portion.

In some examples, the encapsulating portion directly contacts the SMM structure.

In some examples, the encapsulating portion includes an epoxy mold compound (EMC).

In some examples, a critical transformation temperature (CTT) of the SMM structure is approximately equivalent to a thermal cycling temperature of the semiconductor device package.

In some examples, a critical transformation temperature (CTT) of the SMM structure is in a range of about 100° C. to about 300° C.

In some examples, the CTT of the SMM structure is in a range of about 125° C. to about 175° C.

In some examples, the one or more metallization layers include a plurality of metallization layers, and one of the plurality of metallization layers is an SMM layer that includes the SMM structure.

In some examples, the SMM layer has a thickness of about 1 micron.

In some examples, each of the plurality of metallization layers is an SMM layer.

In some examples, the plurality of metallization layers have a combined thickness of about 4 microns.

In some examples, the submount includes a lead frame for the semiconductor device package.

In some examples, the submount includes a direct bonded copper (DBC) substrate or an active metal brazed (AMB) substrate.

In some examples, the submount includes copper.

In some examples, the SMM structure is one or more of a contact, an interconnect, or

a bonding pad for the semiconductor device.

In some examples, the contact is one of a gate contact, a source contact, or a drain contact for the semiconductor device.

In some examples, the SMM structure includes a nitinol alloy.

In some examples, the nitinol alloy is a ternary nitinol alloy comprising nickel, titanium, and a ternary element.

In some examples, the ternary element includes palladium.

In some examples, the ternary nitinol alloy includes a range of about 5% palladium to about 30% palladium.

In some examples, the ternary nitinol alloy includes a range of about 20% palladium to about 24% palladium.

In some examples, the ternary element includes platinum.

In some examples, the ternary nitinol alloy includes a range of about 5% platinum to about 30% platinum.

In some examples, the ternary nitinol alloy includes a range of about 10% platinum to about 12% platinum.

In some examples, the ternary element includes gold.

In some examples, the ternary nitinol alloy includes a range of about 5% gold to about 30% gold.

In some examples, the ternary nitinol alloy includes a range of about 18% gold to about 20% gold.

In some examples, the ternary nitinol alloy includes a range of about 5% ternary element to about 30% ternary element.

In some examples, the ternary nitinol alloy includes a range of about 49% titanium to about 52% titanium.

In some examples, the ternary nitinol alloy includes a range of about 18% nickel to about 46% nickel.

In some examples, the ternary nitinol alloy includes a range of about 21% nickel to about 43% nickel.

In some examples, the SMM structure includes a source contact, a drain contact, or a gate contact for a metal-oxide-semiconductor field-effect transistor (MOSFET).

In some examples, the semiconductor device package further includes a passivation layer.

In some examples, the passivation layer includes silicon nitride.

In some examples, the passivation layer includes a polymer.

In some examples, the polymer includes polyimide.

In some examples, the semiconductor die includes a wide bandgap semiconductor.

In some examples, the semiconductor die includes a silicon carbide-based metal-oxide-semiconductor field-effect transistor (MOSFET).

In some examples, the semiconductor die includes a silicon carbide-based Schottky diode.

In some examples, the semiconductor die includes a Group-III nitride-based high electron mobility transistor (HEMT) device.

Another example embodiment of the present disclosure is directed to a semiconductor device. The semiconductor device includes a semiconductor die and a shape-memory metallization (SMM) structure on the semiconductor die.

In some examples, the SMM structure is one or more of a contact, an interconnect, or a bonding pad for the semiconductor device.

In some examples, the contact is one of a gate contact, a source contact, or a drain contact for the semiconductor device.

In some examples, the SMM structure includes a nitinol alloy.

In some examples, the nitinol alloy is a ternary nitinol alloy comprising nickel, titanium, and a ternary element.

In some examples, the ternary element includes palladium.

In some examples, the ternary nitinol alloy includes a range of about 5% palladium to about 30% palladium.

In some examples, the ternary nitinol alloy includes a range of about 20% palladium to about 24% palladium.

In some examples, the ternary element includes platinum.

In some examples, the ternary nitinol alloy includes a range of about 5% platinum to about 30% platinum.

In some examples, the ternary nitinol alloy includes a range of about 10% platinum to about 12% platinum.

In some examples, the ternary element includes gold.

In some examples, the ternary nitinol alloy includes a range of about 5% gold to about 30% gold.

In some examples, the ternary nitinol alloy includes a range of about 18% gold to about 20% gold.

In some examples, the ternary nitinol alloy includes a range of about 5% ternary element to about 30% ternary element.

In some examples, the ternary nitinol alloy includes a range of about 49% titanium to about 52% titanium.

In some examples, the ternary nitinol alloy includes a range of about 18% nickel to about 46% nickel.

In some examples, the ternary nitinol alloy includes a range of about 21% nickel to about 43% nickel.

In some examples, the semiconductor device further includes a passivation layer.

In some examples, the passivation layer includes silicon nitride.

In some examples, the passivation layer includes a polymer.

In some examples, the polymer includes polyimide.

In some examples, the semiconductor die includes a wide bandgap semiconductor.

In some examples, the semiconductor die includes one or more silicon carbide-based metal-oxide-semiconductor field-effect transistors (MOSFETs).

In some examples, the semiconductor die includes one or more silicon carbide-based Schottky diodes.

In some examples, the semiconductor die includes one or more Group-III nitride-based high electron mobility transistor (HEMT) devices.

In some examples, the SMM structure includes one or more of a silver-cadmium alloy, a gold-cadmium alloy, a copper-aluminum-nickel alloy, a copper-tin alloy, a copper-zinc alloy, a copper-zinc-silicon alloy, a copper-zinc-tin alloy, a copper-zinc-aluminum alloy, an indium-titanium alloy, a nickel-aluminum alloy, an iron-platinum alloy, a manganese-copper alloy, an iron-manganese alloy, or an iron-manganese-silicon alloy.

Another example embodiment of the present disclosure is directed to a semiconductor device. The semiconductor device includes a semiconductor die and a metallization structure on the semiconductor die. The metallization structure includes a ternary nitinol alloy.

In some examples, the metallization structure is a shape-memory metallization (SMM) structure.

In some examples, the metallization structure is one or more of a contact, an interconnect, or a bonding pad for the semiconductor device.

In some examples, the contact is one of a gate contact, a source contact, or a drain contact for the semiconductor device.

In some examples, the ternary nitinol alloy includes nickel, titanium, and a ternary element.

In some examples, the ternary element includes palladium.

In some examples, the ternary nitinol alloy includes a range of about 5% palladium to about 30% palladium.

In some examples, the ternary nitinol alloy includes a range of about 20% palladium to about 24% palladium.

In some examples, the ternary element includes platinum.

In some examples, the ternary nitinol alloy includes a range of about 5% platinum to about 30% platinum.

In some examples, the ternary nitinol alloy includes a range of about 10% platinum to about 12% platinum.

In some examples, the ternary element includes gold.

In some examples, the ternary nitinol alloy includes a range of about 5% gold to about 30% gold.

In some examples, the ternary nitinol alloy includes a range of about 18% gold to about 20% gold.

In some examples, the ternary nitinol alloy includes a range of about 5% ternary element to about 30% ternary element.

In some examples, the ternary nitinol alloy includes a range of about 49% titanium to about 52% titanium.

In some examples, the ternary nitinol alloy includes a range of about 18% nickel to about 46% nickel.

In some examples, the ternary nitinol alloy includes a range of about 21% nickel to about 43% nickel.

In some examples, the semiconductor device further includes a passivation layer.

In some examples, the passivation layer includes silicon nitride.

In some examples, the passivation layer includes a polymer.

In some examples, the polymer includes polyimide.

In some examples, the semiconductor die includes a wide bandgap semiconductor.

In some examples, the semiconductor die includes one or more silicon carbide-based metal-oxide-semiconductor field-effect transistors (MOSFETs).

In some examples, the semiconductor die includes one or more silicon carbide-based Schottky diodes.

In some examples, the semiconductor die includes one or more Group-III nitride-based high electron mobility transistor (HEMT) devices.

Another example embodiment of the present disclosure is directed to a method. The method includes providing a shape-memory metallization (SMM) structure on a semiconductor die. The SMM structure includes a nitinol alloy.

In some examples, the method further includes depositing a passivation layer on the semiconductor die.

In some examples, the method further includes opening the passivation layer to expose the SMM structure and bonding one or more electrical connection structures to the SMM structure.

In some examples, the method further includes attaching an assembly comprising the semiconductor die and the SMM structure to a lead frame and encapsulating the assembly. In some examples, the passivation layer includes silicon nitride.

In some examples, the passivation layer includes a polymer.

In some examples, the polymer includes polyimide.

In some examples, the SMM structure includes a contact, an interconnect, or a bonding pad.

In some examples, the contact is one of a gate contact, a source contact, or a drain contact for a semiconductor device.

In some examples, the nitinol alloy is a ternary nitinol alloy comprising nickel, titanium, and a ternary element.

In some examples, the ternary element includes palladium.

In some examples, the ternary nitinol alloy includes a range of about 5% palladium to about 30% palladium.

In some examples, the ternary nitinol alloy includes a range of about 20% palladium to about 24% palladium.

In some examples, the ternary element includes platinum.

In some examples, the ternary nitinol alloy includes a range of about 5% platinum to about 30% platinum.

In some examples, the ternary nitinol alloy includes a range of about 10% platinum to about 12% platinum.

In some examples, the ternary element includes gold.

In some examples, the ternary nitinol alloy includes a range of about 5% gold to about 30% gold.

In some examples, the ternary nitinol alloy includes a range of about 18% gold to about 20% gold.

In some examples, the ternary nitinol alloy includes a range of about 5% ternary element to about 30% ternary element.

In some examples, the ternary nitinol alloy includes a range of about 49% titanium to about 52% titanium.

In some examples, the ternary nitinol alloy includes a range of about 18% nickel to about 46% nickel.

In some examples, the ternary nitinol alloy includes a range of about 21% nickel to about 43% nickel.

In some examples, the semiconductor die includes a wide bandgap semiconductor.

In some examples, the semiconductor die includes one or more silicon carbide-based metal-oxide-semiconductor field-effect transistors (MOSFETs).

In some examples, the semiconductor die includes one or more silicon carbide-based Schottky diodes.

In some examples, the semiconductor die includes one or more Group-III nitride-based high electron mobility transistor (HEMT) devices.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device package, comprising:
a submount; and
one or more semiconductor die on the submount, the one or more semiconductor die comprising one or more metallization layers, the one or more metallization layers comprising a shape-memory metallization (SMM) structure.

2. The semiconductor device package of claim 1, further comprising an encapsulating portion, wherein the encapsulating portion directly contacts the SMM structure.

3-4. (canceled)

5. The semiconductor device package of claim 1, wherein a critical transformation temperature (CTT) of the SMM structure is approximately equivalent to a thermal cycling temperature of the semiconductor device package.

6. The semiconductor device package of claim 1, wherein a critical transformation temperature (CTT) of the SMM structure is in a range of about 100° C. to about 300° C.

7. (canceled)

8. The semiconductor device package of claim 1, wherein the one or more metallization layers comprise a plurality of metallization layers, and wherein-one each of the plurality of metallization layers is an SMM layer comprising the SMM structure.

9-16. (canceled)

17. The semiconductor device package of claim 1, wherein the SMM structure comprises a ternary nitinol alloy, the ternary nitinol alloy comprising nickel, titanium, and a ternary element.

18. (canceled)

19. The semiconductor device package of claim 17, wherein the ternary element comprises palladium, and wherein the ternary nitinol alloy comprises a range of about 5% palladium to about 30% palladium.

20-21. (canceled)

22. The semiconductor device package of claim 17, wherein the ternary element comprises platinum, and wherein the ternary nitinol alloy comprises a range of about 5% platinum to about 30% platinum.

23-24. (canceled)

25. The semiconductor device package of claim 17, wherein the ternary element comprises gold, and wherein the ternary nitinol alloy comprises a range of about 5% gold to about 30% gold.

26-40. (canceled)

41. A semiconductor device, comprising:
a semiconductor die; and
a shape-memory metallization (SMM) structure on the semiconductor die.

42. The semiconductor device of claim 41, wherein the SMM structure is one or more of a contact, an interconnect, or a bonding pad for the semiconductor device.

43. (canceled)

44. The semiconductor device of claim 41, wherein the SMM structure comprises a nitinol alloy, and wherein the nitinol alloy is a ternary nitinol alloy comprising nickel, titanium, and a ternary element.

45-54. (canceled)

55. The semiconductor device of claim 44, wherein the ternary nitinol alloy comprises a range of about 5% ternary element to about 30% ternary element.

56. The semiconductor device of claim 44, wherein the ternary nitinol alloy comprises a range of about 49% titanium to about 52% titanium.

57. The semiconductor device of claim 44, wherein the ternary nitinol alloy comprises a range of about 18% nickel to about 46% nickel.

58-62. (canceled)

63. The semiconductor device of claim 41, wherein the semiconductor die comprises a wide bandgap semiconductor.

64. The semiconductor device of claim 41, wherein the semiconductor die comprises one or more silicon carbide-based metal-oxide-semiconductor field-effect transistors (MOSFETs), one or more silicon carbide-based Schottky diodes, or one or more Group-III nitride-based high electron mobility transistor (HEMT) devices.

65-66. (canceled)

67. The semiconductor device of claim 41, wherein the SMM structure comprises one or more of a silver-cadmium alloy, a gold-cadmium alloy, a copper-aluminum-nickel alloy, a copper-tin alloy, a copper-zinc alloy, a copper-zinc-silicon alloy, a copper-zinc-tin alloy, a copper-zinc-aluminum alloy, an indium-titanium alloy, a nickel-aluminum alloy, an iron-platinum alloy, a manganese-copper alloy, an iron-manganese alloy, or an iron-manganese-silicon alloy.

68-93. (canceled)

94. A method, comprising:
providing a shape-memory metallization (SMM) structure on a semiconductor die;
wherein the SMM structure comprises a nitinol alloy.

95. The method of claim 94, further comprising:
depositing a passivation layer on the semiconductor die;
opening the passivation layer to expose the SMM structure;
bonding one or more electrical connection structures to the SMM structure;
attaching an assembly comprising the semiconductor die and the SMM structure to a lead frame; and
encapsulating the assembly.

96-120. (canceled)
